(19) United States
(12) Patent Application Publication
(10) Pub. No.: US 2026/0015264 A1
(43) Pub. Date: Jan. 15, 2026

(54) METHOD FOR RECYCLING SULFURIC ACID

(71) Applicant: INDUSTRIAL TECHNOLOGY RESEARCH INSTITUTE, Hsinchu (TW)

(72) Inventors: Hsin-Ju YANG, Baoshan Township (TW); Guan-You LIN, Zhubei City (TW); Wei-Chieh JEN, Taichung City (TW); Yi-Tze TSAI, Hemei Vil. (TW)

(73) Assignee: INDUSTRIAL TECHNOLOGY RESEARCH INSTITUTE, Hsinchu (TW)

(21) Appl. No.: 19/337,610

(22) Filed: Sep. 23, 2025

Related U.S. Application Data
(62) Division of application No. 18/740,807, filed on Jun. 12, 2024.
(60) Provisional application No. 63/582,595, filed on Sep. 14, 2023.

(30) Foreign Application Priority Data
Apr. 16, 2024 (TW) 113114077

(51) Int. Cl. C02F 1/32; C02F 101/10; C02F 103/34; H01L 21/67

(52) U.S. Cl. CPC C02F 1/325; H01L 21/67017; H01L 21/67115; C02F 2101/10; C02F 2103/346; C02F 2201/005; C02F 2201/3227; C02F 2209/02; C02F 2209/40

(57) ABSTRACT

A device for recycling sulfuric acid is provided. A container has an inner space. An inlet is located on the first side of the container for introducing a liquid containing sulfuric acid and hydrogen peroxide through a pump. An outlet is located on the second side of the container for exhausting the treated liquid from the container, and the first side and the second side are opposite sides. IR lamp and UV lamp are located in the inner space of the container for making contact with the liquid. IR radiation emitted from the IR lamp and UV radiation emitted from the UV lamp decompose the hydrogen peroxide in the liquid to water and oxygen. The IR radiation heats the liquid to 90° C. to 130° C., and the oxygen is exhausted through the air hole.

### CROSS REFERENCE TO RELATED APPLICATIONS

This application is a Divisional of pending U.S. patent application Ser. No. 18/740,807, filed on Jun. 12, 2024 and entitled “DEVICE AND METHOD FOR RECYCLING SULFURIC ACID”, which claims the benefit of U.S. Provisional Application No. 63/582,595, filed on Sep. 14, 2023, and is based on, and claims priority from, Taiwan Application Serial Number 113114077, filed on Apr. 16, 2024, the disclosures of which are hereby incorporated by reference herein in its entirety.

### TECHNICAL FIELD

The disclosure relates to a device and a method of recycling sulfuric acid.

### BACKGROUND

In the semiconductor manufacturing process, electronic-grade sulfuric acid is used to prepare a Caro's acid solution to clean the wafers, and the waste sulfuric acid produced by the cleaning process is the process waste liquid with the highest volume. The production of waste sulfuric acid reached 365,000 tons in 2021. As the semiconductor industry expands, the production of waste sulfuric acid (which is difficult to remove) is estimated to reach 516,000 tons. Waste sulfuric acid that is made up of more than 50 wt % of sulfuric acid and 1 wt % to 5 wt % of hydrogen peroxide cannot be directly re-used due to its strong oxidizing properties. For the main pollutants in the waste sulfuric acid such as hydrogen peroxide, the current treatment is to add hydrochloric acid as a catalyst to degrade the hydrogen peroxide until it is less than or equal to 50 mg/L. However, this process generates hazardous substances such as chlorine gas, and it leaves chloride ions in the purified sulfuric acid. Thus, this process is not the best purification scheme. In addition, a commercial enzyme can be added to remove the hydrogen peroxide from the waste sulfuric acid, but it is expensive and not very effective. Moreover, the enzyme also has problems of drug residues and acid quality change, so it is difficult to remove the enzyme to use the acid.

Accordingly, a novel method for treating the waste sulfuric acid to improve quality of the recycled sulfuric acid is called for.

### SUMMARY

One embodiment of the disclosure provides a device for recycling sulfuric acid, including a container, an inlet, an outlet, an IR (infrared) lamp, a UV (ultraviolet) lamp, a bracket, and a lid. The container has an inner space. The inlet is located on the first side of the container. The inlet is used for introducing a liquid containing sulfuric acid and hydrogen peroxide through a pump. The outlet is located on the second side of the container. The outlet is used for exhausting the treated liquid from the container. The first side and the second side are opposite sides. The IR lamp is located in the inner space of the container. The IR lamp is for making contact with the liquid. The UV lamp is located in the inner space of the container. The UV lamp is used for making contact with the liquid. The bracket is located in the inner space of the container. The bracket joins the IR lamp and the UV lamp. The lid covers the top side of the container. The lid has an air hole that is connected to an exhaust device. IR radiation emitted from the IR lamp and UV radiation emitted from the UV lamp decompose the hydrogen peroxide in the liquid to water and oxygen. The IR radiation heats the liquid to 90° C. to 130° C., and the oxygen is exhausted through the air hole.

In some embodiments, the device further includes a three-way valve connected to the outlet for exhausting the oxygen.

In some embodiments, the IR radiation has a wavelength of 1500 nm to 6500 nm.

In some embodiments, the UV radiation has a wavelength of 230 nm to 275 nm.

In some embodiments, each of the IR radiation and the UV radiation has an energy density of 0.1 W/cm² to 16 W/cm².

In some embodiments, the IR radiation and the UV radiation have an energy density ratio of 4:1 to 20:1.

In some embodiments, the device further includes other IR lamps and other UV lamps, wherein the total cross-sectional area of the IR lamps and the cross-sectional area of the container have a ratio of 1:100 to 5:100, and the total cross-sectional area of the UV lamps and the cross-sectional area of the container have a ratio of 1:100 to 5:100.

In some embodiments, the IR lamps are arranged as a first circle in a cross-section of the container, the UV lamps are arranged as a second circle in the cross-section of the container, the first circle and the second circle are concentric, and a diameter of the first circle is larger than a diameter of the second circle.

In some embodiments, the liquid introduced from the inlet has a flow rate of 0.5 m/hour to 3 m/hour.

In some embodiments, the liquid has a sulfuric acid concentration of 50 wt % to 70 wt %.

In some embodiments, the liquid has a hydrogen peroxide concentration of 10000 mg/L to 60000 mg/L, and the treated liquid has a hydrogen peroxide concentration of less than or equal to 50 mg/L.

In some embodiments, a sidewall of the container has a concave and convex structure.

One embodiment of the disclosure provides a method of recycling sulfuric acid, including: providing a liquid into a container, wherein the liquid contains sulfuric acid and hydrogen peroxide; decomposing the hydrogen peroxide in the liquid to water and oxygen using IR radiation and UV radiation, wherein the liquid is heated to 90° C. to 130° C. by the IR radiation; and collecting the treated liquid.

In some embodiments, the method further includes removing the oxygen during the decomposition of the hydrogen peroxide to water and oxygen.

In some embodiments, the IR radiation has a wavelength of 1500 nm to 6500 nm.

In some embodiments, the UV radiation has a wavelength of 230 nm to 275 nm.

In some embodiments, each of the IR radiation and the UV radiation has an energy density of 0.1 W/cm² to 16 W/cm².

In some embodiments, the IR radiation and the UV radiation have an energy density ratio of 4:1 to 20:1.

In some embodiments, the liquid has a sulfuric acid concentration of 50 wt % to 70 wt %.

In some embodiments, the liquid has a hydrogen peroxide concentration of 10000 mg/L to 60000 mg/L, and the treated liquid has a hydrogen peroxide concentration of less than or equal to 50 mg/L.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIG. 1 shows a perspective view of a device for recycling sulfuric acid in some embodiments.

FIG. 2 shows a plurality of container connected in series in some embodiments.

FIG. 3 shows a cross-sectional view of a bracket, IR lamps, and UV lamps in the device for recycling sulfuric acid of FIG. 1 along a cross section a-a′.

FIG. 4 shows a cross-sectional view of an arrangement of the IR lamps and the UV lamps in the device for recycling sulfuric acid of FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

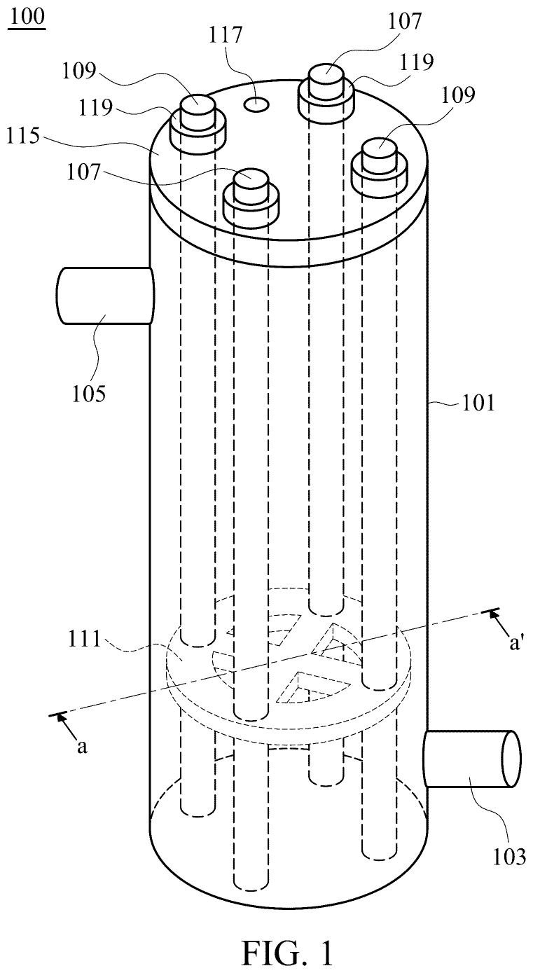

One embodiment of the disclosure provides a device 100 of recycling sulfuric acid, as shown in FIG. 1. The device 100 includes a container 101 having an inner space. In some embodiments, the container 101 is composed of poly(tetrafluoroethene) (PTFE) or another suitable material. PTFE is resistant to acid corrosion and heat, and has a certain degree of reflecting IR and UV, which is beneficial to treat a liquid as described below. The container 101 in FIG. 1 is a cylinder but being not limited thereto. One skilled in the art may adopt any reasonable container shape without departing from the scope of the disclosure. For example, the cross section of the container 101 is not only circle but also square, rectangular, hexagonal, oval, or any other shape, as long as it is convenient to set up and operate. On the other hand, the container 101 may have a volume of 1 L to 20 L but being not limited thereto. If the volume of the container 101 is too small, the amount of liquid that can be treated in a constant period of time will be insufficient. If the volume of the container 101 is too large, it will be difficult to be assembled and cleaned.

The device 100 also includes an inlet 103 located at a first side of the container 101 for introducing a liquid containing sulfuric acid and hydrogen peroxide through a pump. The inlet 103 can be connected to a process chamber (e.g. etching chamber or cleaning chamber, not shown) generating the liquid through a pipeline. In general, the liquid generated by the process chamber may contain a little solid impurity. The solid impurity can be removed by a filtering net, and the liquid was then introduced into the container 101. The pipeline connecting the process chamber and the inlet 103 can be composed of PTFE or polypropylene (PP), which depends on the temperature of the liquid generated by the process chamber. If the liquid temperature is high (e.g. higher than 80° C.), the pipeline can be composed of the thermal resistant PTFE. If the liquid temperature is low (e.g. room temperature), the pipeline can be composed of PP to lower the cost.

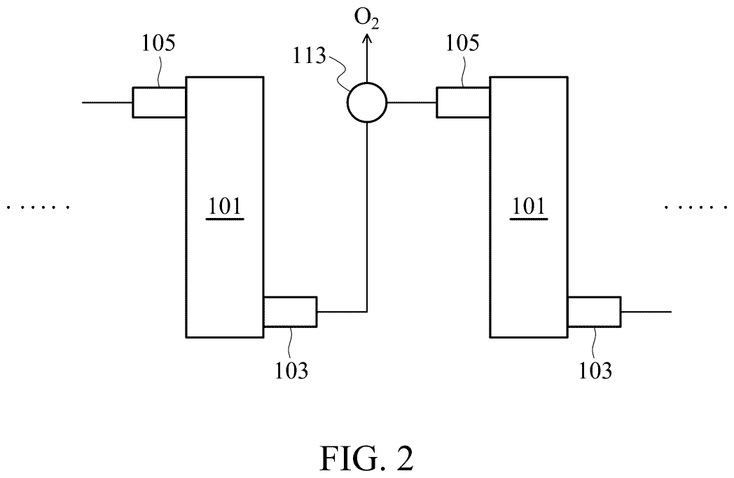

The device 100 also includes an outlet 105 located at a second side of the container 101 for exhausting a treated liquid from the container 101, and the first side is opposite to the second side. The outlet 105 can be connected to a colleting tank (not shown), or connected to an inlet 103 of another device 100. For example, a plurality of devices 100 can be connected in series, and the outlet 105 of each if the device 100 can be connected to the inlet 103 of the next device 100 by pipelines, as shown in FIG. 2. As such, the amount of the liquid that can be treated per unit of time can be increased. Using a plurality of devices 100 of small volume connected in series (rather than a single device of large volume) is beneficial to clean and maintain in practice. For example, after one of the plurality of devices 100 connected in series is replaced with a new device 100, the liquid can be continuously treated and the replaced device 100 can be cleaned and maintained at the same time. However, when a single device of large volume is cleaned and maintained, the treatment of the liquid should be stopped. Even if another single device of large volume is prepared as backup, its cost of assembling and disassembling is still higher than that of the devices 100 of small volume connected in series.

The device 100 also includes IR lamp 107 located in the inner space of the container 101 for making contact with the liquid. Note that the IR lamps 107 are not installed on the sidewall of the container 101, which may increase the efficiency of the IR lamps 107. The tubes of the IR lamps 107 are composed of quartz to avoid the acid corrosion issue of the liquid.

The device 100 also includes UV lamp 109 located in the inner space of the container 101 for making contact with the liquid. Note that the UV lamps 109 are not installed on the sidewall of the container 101, which may increase the efficiency of the UV lamps 109. The tubes of the UV lamps 107 are composed of quartz to avoid the acid corrosion issue of the liquid. Note that the volume of the liquid tends to be not higher than the outlet 105, because an overly high volume of the liquid will negatively influence the lifespan of the IR lamps 107 and the UV lamps 109.

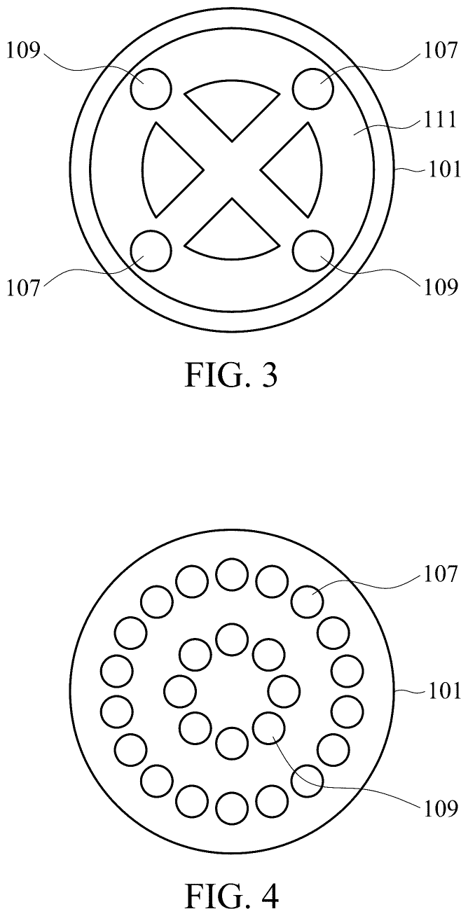

The device 100 also includes a bracket 111 located in the inner space of the container 101 for joining the IR lamp 107 and the UV lamp 109. The structure of the bracket 111 is shown as the cross-sectional view of FIG. 3. FIG. 3 shows a cross-sectional view of the bracket 111, the IR lamps 107, and the UV lamps 109 in the device 100 of recycling sulfuric acid of FIG. 1 along a cross section a-a′. In FIG. 3, the bracket 111 has a cross in a circle frame to increase support degree, and the IR lamps 107 and the UV lamps 109 are respectively located at the end points of the cross. It should be understood that FIG. 3 is only for illustration rather than liming the scope of the disclosure. Alternatively, the frame of the bracket 111 can be other shapes such as square, hexagon, or another suitable shape, and the cross can be changed to other pattern such as star (e.g. *). In some embodiments, a plurality of the brackets 111 can be arranged at intervals to increase the support degree, and spaces between the adjacent brackets 111 and the patterns of the brackets 111 can be same or different. Take FIG. 3 as an example, the pattern of the bracket 111 has a turbulent effect, which helps to uniformly mix the liquid flowing from the inlet 103 to the outlet 105. In addition, a sidewall of the container 101 can be flat as shown in FIG. 1, or has a specific concave and convex structure (not shown) to further enhance the turbulent effect.

The device 100 also includes a lid 115 covering the top side of the container 101 and having an air hole 117, wherein the air hole 117 is connected to an exhaust device (not shown), as shown in FIG. 1. The lamp bases of the IR lamps 107 and the UV lamps 109 protrudes out of the lid 115 to connect to a power source, and brackets 119 can be optionally located on the lid 115 to support the terminals of the IR lamps 107 and the UV lamps 109.

In some embodiments, IR radiation emitted from the IR lamps 107 and UV radiation emitted from the UV lamps 109 decompose the hydrogen peroxide in the liquid to water and oxygen, the IR radiation heats the liquid to 90° C. to 130° C., and the oxygen is exhausted from the air hole 117. If the temperature of the liquid is too low, the efficiency of decomposing the hydrogen peroxide will be insufficient. If the temperature of the liquid is too high, a large amount of oxygen will be quickly generated and cannot be easily controlled. The IR radiation not only heats the liquid, but also assists the UV radiation to decompose the hydrogen peroxide. If the IR lamps 107 are not adopted (e.g. only the UV lamps 109 are adopted and the liquid is heated by another heating equipment such as a hot plate), the effect of decomposing the hydrogen peroxide will be decreased.

The device 100 of recycling sulfuric acid as shown in FIG. 2 may optionally further include a three-way valve 113 connected to the outlet 105 for exhausting the oxygen. The three-way valve 113 can be disposed between the outlet 105 of the container 101 and a collecting tank (not shown), or between the outlet 105 of the container 101 and the inlet 103 of the next container 101. The oxygen generated by decomposing the hydrogen peroxide can be exhausted from the described air hole 117 and the three-way valve 113, and the oxygen will not be accumulated in the container 101 to negatively influence the step of treating the liquid. On the other hand, the three-way valve 113 can be connected to the outlet 105 of the container 101 and the inlet 103 of the next container 101 (or the collecting tank) through pipelines. In addition, the three-way valve 113 can be connected to an exhausting device (not shown) as the described air hole 117.

In some embodiments, the IR radiation has a wavelength of 1500 nm to 6500 nm to correspond to the wavelength of the major absorption peak of hydrogen peroxide, such as 2800 nm to 2900 nm, 3500 nm to 3600 nm, and 6000 nm to 6500 nm. If the wavelength of the IR radiation is not in the above ranges, the decomposition effect of the hydrogen peroxide will not be efficiently enhanced.

In some embodiments, the UV radiation has a wavelength of 230 nm to 275 nm. If the wavelength of the UV radiation is not in the above range, the hydrogen peroxide cannot be efficiently decomposed.

In some embodiments, each of the IR radiation and the UV radiation has an energy density of 0.1 W/cm² to 16 W/cm². If the energy density of the IR radiation or the UV radiation is too low, the hydrogen peroxide cannot be efficiently decomposed. If the energy density of the IR radiation or the UV radiation is too high, it will be difficult to control the reaction temperature, and the sulfuric acid or the hydrogen peroxide will boil, increasing the operational risk.

In some embodiments, the IR radiation and the UV radiation have an energy density ratio of 4:1 to 20:1. If the ratio is too low, the reaction rate cannot be enhanced and the treatment effect will be poor. If the ratio is too high, it will be difficult to control the reaction temperature, and the sulfuric acid or the hydrogen peroxide will boil, increasing the operational risk.

In some embodiments, the device further includes other IR lamps 107 and other UV lamps 109, wherein the total cross-sectional area of the IR lamps 107 and the cross-sectional area of the container 101 have a ratio of 1:100 to 5:100, and the total cross-sectional area of the UV lamps 109 and the cross-sectional area of the container 101 have a ratio of 1:100 to 5:100. If the total cross-sectional area of the IR lamps 107 is too small, the heating period will be too long and the predetermined reaction temperature cannot be achieved. If the total cross-sectional area of the IR lamps 107 is too large, it will be difficult to control the reaction temperature, and the sulfuric acid or the hydrogen peroxide will boil, increasing the operational risk.

In some embodiments, the IR lamps 107 are arranged as a first circle in a cross-section of the container 101, the UV lamps 109 are arranged as a second circle in the cross-section of the container 101, the first circle and the second circle are concentric, and a diameter of the first circle is larger than a diameter of the second circle, as shown in FIG. 4. FIG. 4 shows a cross-sectional view of the arrangement of the IR lamps and the UV lamps in the device for recycling sulfuric acid of FIG. 1. It should be understood that FIG. 4 only shows the cross-section of the IR lamps 107 and the UV lamps (e.g. the bracket 111 are not shown in this cross-section). In some embodiments, the bracket 111 can be disposed between the IR lamps 107 and the UV lamps 109 to be fixed in the container 101. FIG. 4 is only for illustration rather than liming the scope of the disclosure. One skilled in the art may arrange a plurality of IR lamps 107 and a plurality of UV lamps 109 in any manner. For example, the IR lamps 107 and the UV lamps 109 can be alternately to each other and arranged as a circle. No matter how the IR lamps 107 and the UV lamps 109 are arranged, the purpose is achieving the maximum and most uniform IR and UV distribution effects with minimum energy consumption. As such, the IR radiation and the UV radiation may decompose the hydrogen peroxide in the liquid, and the IR radiation may heat the liquid.

In some embodiments, the liquid introduced from the inlet has a flow rate of 0.5 m/hour to 3 m/hour. If the flow rate of the introduced liquid is too fast, the effect of decomposing the hydrogen peroxide will be insufficient. If the flow rate of the introduced liquid is too slow, the uniformity of the liquid will be poor and the effect of decomposing the hydrogen peroxide will be lowered.

In some embodiments, the liquid has a sulfuric acid concentration of 50 wt % to 70 wt %. The sulfuric acid is not substantially influenced by the above steps. However, the hydrogen peroxide is decomposed to form water and oxygen, such that the sulfuric acid concentration in the treated liquid will be slightly decreased (e.g. diluted by the water generated by decomposing the hydrogen peroxide).

In some embodiments, the liquid has a hydrogen peroxide concentration of 10000 mg/L to 60000 mg/L, and the treated liquid has a hydrogen peroxide concentration of less than or equal to 50 mg/L. In the treated liquid, the hydrogen peroxide may have a concentration of less than or equal to 40 mg/L, less than or equal to 30 mg/L, less than or equal to 10 mg/L, or even lower than detection limit of the instrument. In some embodiments, the treated liquid includes a high concentration of sulfuric acid and an extremely low concentration (or even no) hydrogen peroxide, thereby being used in a lower level industry without further purification. In addition, the method does not add any auxiliary agent (e.g. hydrochloric acid) into the liquid, such that the treated liquid is substantially composed of water and sulfuric acid (and a little hydrogen peroxide, if present) without any other auxiliary agent.

In some embodiments, the method of recycling sulfuric acid may include providing a liquid into a container, wherein the liquid contains sulfuric acid and hydrogen peroxide. The container can be the container 101 of the described device 100 or another container. Subsequently, the hydrogen peroxide in the liquid is decomposed to water and oxygen by IR radiation and UV radiation, and the liquid is heated to 90° C. to 130° C. by the IR radiation. Finally, the treated liquid is collected. The wavelengths and energy density of the IR radiation and the UV radiation, and the sulfuric acid concentration and the hydrogen peroxide concentration of the liquid and the treated liquid in this method are similar to those mentioned above and will not be repeated here. Accordingly, the disclosure provides the method and the device for recycling sulfuric acid, which can decompose hydrogen peroxide in the liquid and efficiently recycle sulfuric acid without adding any auxiliary agent. Compared to the conventional method adding the auxiliary agent, the disclosed method may prevent the reaction process from generating hazardous gases (such as chlorine gas or NOx) and damaging the treatment equipment and related pipelines. In addition, the recycled sulfuric acid recycled in this disclosure without adding auxiliary agent has high purity and can be directly used in other industries such as the printed circuit board industry. Compared to the scheme only utilizing the UV radiation, the disclosure combines the UV radiation and the IR radiation to efficiently increase the reaction rate (e.g. enhancing the decomposition efficiency of the hydrogen peroxide in the same treating period).

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

### EXAMPLES

In following Examples, the concentration of the hydrogen peroxide was analyzed according to a method disclosed by Steller (Spectrophotometric Determination of Hydrogen Peroxide Using Potassium (IV) Oxalate”, Analyst, Oct., 105, 950-954 (1980)). For example, an acidic solution of potassium titanium oxalate (0.05 M of potassium titanium oxalate in 3M of H₂SO₄ solution) and different amounts of hydrogen peroxide were mixed to form different amounts of a yellow complex of tetravalent titanium, which were analyzed by a spectrophotometer to measure their absorbance at 400 nm for then calibrating a calibration line. 5 mL of the acidic solution of potassium titanium oxalate, appropriate amount of a sample, and de-ionized water were uniformly mixed during the analyzing, and the absorbance at 400 nm of the mixture was measured. The concentration of the hydrogen peroxide in the sample could be calculated by the absorbance and the calibration line.

### Comparative Example 1

200 mL of a mixture liquid of sulfuric acid and hydrogen peroxide was prepared, which contained 60 wt % of sulfuric acid and 50000 mg/L of hydrogen peroxide. The mixture liquid was heated to 90° C. by a hot plate, and the hydrogen peroxide in the mixture liquid was tracked to calculate the decomposition reaction rate (0.0017 min−1) and the decomposition efficiency (5%) of the hydrogen peroxide after 1 hour treatment.

### Comparative Example 2

200 mL of a mixture liquid of sulfuric acid and hydrogen peroxide was prepared, which contained 60 wt % of sulfuric acid and 50000 mg/L of hydrogen peroxide. The mixture liquid was heated to 90° C. by a hot plate and irradiated by UV radiation (254 nm/0.22 W/cm²), and the hydrogen peroxide in the mixture liquid was tracked to calculate the decomposition reaction rate (0.0021 min⁻¹) and the decomposition efficiency (14%) of the hydrogen peroxide after 1 hour treatment.

### Comparative Example 3

200 mL of a mixture liquid of sulfuric acid and hydrogen peroxide was prepared, which contained 60 wt % of sulfuric acid and 50000 mg/L of hydrogen peroxide. The mixture liquid was irradiated by IR radiation (1500 nm to 6500 nm/4.21 W/cm²), thereby heating the mixture liquid to 90° C. The hydrogen peroxide in the mixture liquid was tracked to calculate the decomposition reaction rate (0.0026 min−1) and the decomposition efficiency (18%) of the hydrogen peroxide after 1 hour treatment.

### Comparative Example 4

200 mL of a mixture liquid of sulfuric acid and hydrogen peroxide was prepared, which contained 60 wt % of sulfuric acid and 50000 mg/L of hydrogen peroxide. The mixture liquid was irradiated by IR radiation (1500 nm to 6500 nm/4.21 W/cm²), thereby heating the mixture liquid to 105° C. The hydrogen peroxide in the mixture liquid was tracked to calculate the decomposition reaction rate (0.0039 min⁻¹) and the decomposition efficiency (28%) of the hydrogen peroxide after 1 hour treatment.

### Comparative Example 5

200 mL of a mixture liquid of sulfuric acid and hydrogen peroxide was prepared, which contained 60 wt % of sulfuric acid and 50000 mg/L of hydrogen peroxide. The mixture liquid was irradiated by IR radiation (1500 nm to 6500 nm/4.21 W/cm²), thereby heating the mixture liquid to 120° C. The hydrogen peroxide in the mixture liquid was tracked to calculate the decomposition reaction rate (0.0073 min⁻¹) and the decomposition efficiency (46%) of the hydrogen peroxide after 1 hour treatment.

### Comparative Example 6

200 mL of a mixture liquid of sulfuric acid and hydrogen peroxide was prepared, which contained 60 wt % of sulfuric acid and 55000 mg/L of hydrogen peroxide. The mixture liquid was irradiated by IR radiation (1500 nm to 6500 nm/4.21 W/cm²), thereby heating the mixture liquid to 130° C. The hydrogen peroxide in the mixture liquid was tracked to calculate the decomposition reaction rate (0.0173 min⁻¹) and the decomposition efficiency (68%) of the hydrogen peroxide after 1 hour treatment.

### Example 1

A mixture liquid of sulfuric acid and hydrogen peroxide was prepared, which contained 60 wt % of sulfuric acid and 47500 mg/L of hydrogen peroxide. The mixture liquid was irradiated by IR radiation (1500 nm to 6500 nm/4.21 W/cm²) and UV radiation (254 nm/0.22 W/cm²), thereby heating the mixture liquid to 130° C. The hydrogen peroxide in the mixture liquid was tracked to calculate the decomposition reaction rate (0.0239 min⁻¹) and the decomposition efficiency (about 84%) of the hydrogen peroxide after 1 hour treatment. The treated mixture liquid had a sulfuric acid concentration of 60 wt % and a hydrogen peroxide concentration of 50 mg/L.

### Example 2

A waste liquid of sulfuric acid and hydrogen peroxide was generated by a factory, which contained 76 wt % of sulfuric acid and 6250 mg/L of hydrogen peroxide. The mixture liquid was irradiated by IR radiation (1500 nm to 6500 nm/4.21 W/cm²) and UV radiation (254 nm/0.22 W/cm²), thereby heating the mixture liquid to 130° C. The hydrogen peroxide in the mixture liquid was tracked to calculate the decomposition reaction rate (0.0228 min⁻¹) and the decomposition efficiency (about 82%) of the hydrogen peroxide after 1 hour treatment. The treated mixture liquid had a sulfuric acid concentration of 76 wt % and a hydrogen peroxide concentration of 50 mg/L.

### Example 3

Referring to FIG. 1, a cylinder container having a diameter of 40 cm and a length of 180 cm was selected. Four IR lamps (having a diameter of 3 cm, a length of 180 cm, an emission wavelength of 1500 nm to 6500 nm, and an energy density of 9.27 W/cm²) and three UV lamps (having a diameter of 3 cm, a length of 180 cm, an emission wavelength of 253.7 nm, and an energy density of 1.02 W/cm²) were arranged in the container. The arrangement of the IR lamps and the UV lamps could refer to FIG. 4.

A mixture liquid of sulfuric acid and hydrogen peroxide was prepared, which contained 60 wt % of sulfuric acid and 47500 mg/L of hydrogen peroxide. The mixture liquid was introduced into the container from the inlet at the bottom side of the container, and the flow rate of the mixture liquid was 2.59 m/hour. The mixture liquid was irradiated by the IR radiation and the UV radiation, and the mixture liquid was heated to 130° C. The air hole of the lid was connected to an exhausting device to exhaust the generated oxygen. The treated mixture liquid passing through the three-way valve (for exhausting the oxygen in the mixture liquid) was introduced to the inlet at the bottom side of the container, such that the treated mixture liquid was circulated back to the container. The hydrogen peroxide in the mixture liquid was tracked to calculate the decomposition reaction rate (0.024 min⁻¹) and the decomposition efficiency (about 85%) of the hydrogen peroxide after 1 hour treatment. The treated mixture liquid had a sulfuric acid concentration of 60 wt % and a hydrogen peroxide concentration of 50 mg/L.

It will be apparent to those skilled in the art that various modifications and variations can be made to the disclosed methods and materials. It is intended that the specification and examples be considered as exemplary only, with the true scope of the disclosure being indicated by the following claims and their equivalents.

What is claimed is:

1. A method for recycling sulfuric acid, comprising:
providing a liquid into a container, wherein the liquid contains sulfuric acid and hydrogen peroxide;
decomposing the hydrogen peroxide in the liquid to water and oxygen using IR radiation and UV radiation, and the liquid is heated to 90° C. to 130° C. by the IR radiation; and
collecting a treated liquid.

2. The method as claimed in claim 1, further comprising removing the oxygen during decomposition of the hydrogen peroxide to water and oxygen.

3. The method as claimed in claim 1, wherein the IR radiation has a wavelength of 1500 nm to 6500 nm.

4. The method as claimed in claim 1, wherein the UV radiation has a wavelength of 230 nm to 275 nm.

5. The method as claimed in claim 1, wherein each of the IR radiation and the UV radiation has an energy density of 0.1 W/cm² to 16 W/cm².

6. The method as claimed in claim 1, wherein the IR radiation and the UV radiation have an energy density ratio of 4:1 to 20:1.

7. The method as claimed in claim 1, wherein the liquid has a sulfuric acid concentration of 50 wt % to 70 wt %.

8. The method as claimed in claim 1, wherein the liquid has a hydrogen peroxide concentration of 10000 mg/L to 60000 mg/L, and the treated liquid has a hydrogen 2 peroxide concentration of less than or equal to 50 mg/L.

9. The method as claimed in claim 1, wherein a sidewall of the container has a concave and convex structure.
